(19) United States
(12) Patent Application Publication
(10) Pub. No.: US 2011/0290185 A1
(43) Pub. Date: Dec. 1, 2011

(54) SUBSTRATE COOLING DEVICE AND SUBSTRATE TREATMENT SYSTEM

(75) Inventors: Ryuta Ihara, Kanagawa-ken (JP); Hideyuki Nitta, Kanagawa-ken (JP); Yoshinori Kawagoe, Kanagawa-ken (JP)

(73) Assignee: SHIBAURA MECHATRONICS CORPORATION, Kanagawa-ken (JP)

(21) Appl. No.: 13/133,491

(22) PCT Filed: Dec. 2, 2009
(86) PCT No.: PCT/JP2009/006550

§ 371 Date: Aug. 22, 2011

(30) Foreign Application Priority Data
Dec. 12, 2008 (JP) 2008-317016

(51) Int. Cl. C23C 16/44

(52) U.S. Cl. 118/724

(57) ABSTRACT

A substrate cooling device configured to cool a substrate after a treatment, the device includes: a housing having a space configured to house a substrate internally; a pair of holder sections provided so as to face an inner wall of the housing, and including a groove section supporting an end neighborhood of the substrate; and a pair of cooling sections including a cooling mechanism provided to sandwich the pair of holder sections in a direction crossing a direction in which the holder sections face each other. According to the invention, a time for cooling the substrate after the treatment can be reduced.

### TECHNICAL FIELD

This invention relates to a substrate cooling device and a substrate treatment system.

### BACKGROUND ART

A substrate treatment device for performing plasma treatment and thermal treatment to a substrate such as a wafer and a glass substrate has been known. In this case, for example, in manufacturing an electronic device or the like, treatments to a substrate has been performed in a clean room having a suppressed number of particles. Recently, in order to suppress particles from attaching to a substrate when transferring the substrate in the clean room, a sealed-type container called FOUP (Front Opening Unified Pod) has been used.

Generally, FOUP is often made of a resin material and has a low heatproof temperature. Thus, direct housing a substrate with a high temperature immediately after the treatment may deform or damage the FOUP.

Here, a cooling device has been proposed for lowering a substrate temperature after the treatment (see Patent Citations 1, 2).

Patent Citation 1 discloses a substrate treatment device including a cooling gas spray nozzle spraying a gas toward a substrate. According to this substrate treatment device, the substrate temperature after the treatment can be reduced. However, increasing gas temperature during flowing of the sprayed gas along a major surface of the substrate may deteriorate a cooling effect on downstream side. Therefore, reduction of the cooling time may be impossible.

Patent Citation 2 discloses a cooling stage cooling a placed substrate by flowing a cooling medium into inside. This cooling stage can reduce the substrate temperature after the treatment. However, because the cooling stage is provided only on one major surface side of the substrate, the cooling effect may be deteriorated. Therefore, reduction of the cooling time may be impossible. In this case, if a contact area between the cooling stage and the substrate is increased, heat exchange due to thermal conduction can be increased. However, if the heat exchange due to the thermal conduction is increased, because a cooling rate is too rapid, the substrate may be damaged. Increasing contact area may cause occurrence of scratches and particles.

### CITATION LIST

### Patent Literature

[Patent Citation 1] JP-A 2005-50955

[Patent Citation 2] JP-A 2000-323549

### SUMMARY OF INVENTION

### Technical Problem

This invention provides a substrate cooling device and a substrate treatment system capable of reducing a time for cooling a substrate after a treatment.

### Solution to Problem

According to an aspect of an embodiment of the invention, there is provided a substrate cooling device configured to cool a substrate after a treatment, the device comprising: a housing having a space configured to house a substrate internally; a pair of holder sections provided so as to face an inner wall of the housing, and including a groove section supporting an end neighborhood of the substrate; and a pair of cooling sections including a cooling mechanism provided to sandwich the pair of holder sections in a direction crossing a direction in which the holder sections face each other.

According to another aspect of the invention, there is provided a substrate treatment system comprising: a treatment device configured to perform a treatment of a substrate; a housing device configured to house the substrate; a substrate cooling device; and a transfer device configured to transfer the substrate between the treatment device and the substrate cooling device and between the substrate cooling device and the housing device, the substrate cooling device configured to cool the substrate after the treatment, the device including: a housing having a space configured to house the substrate internally; a pair of holder sections provided so as to face an inner wall of the housing, and including a groove section supporting an end neighborhood of the substrate; and a pair of cooling sections including a cooling mechanism provided to sandwich the pair of holder sections in a direction crossing a direction in which the holder sections face each other.

### ADVANTAGEOUS EFFECTS OF INVENTION

According to the invention, a substrate cooling device and a substrate treatment system capable of reducing a time for cooling a substrate after a treatment are provided.

### BRIEF DESCRIPTION OF DRAWINGS

FIG. 1 is a schematic view for illustrating a substrate cooling device according to a first embodiment of the invention.

FIG. 2 is a sectional view as viewed along arrows A-A in FIG. 1.

FIG. 3 is a schematic view for illustrating a substrate cooling device according to a second embodiment of the invention.

FIG. 4 is a sectional view as viewed along arrows B-B in FIG. 3.

FIG. 5 is a schematic view for illustrating a substrate treatment system according to a third embodiment of the invention.

FIG. 6 is a schematic sectional view for illustrating the configuration of a treatment chamber.

FIG. 7 is a schematic view for illustrating the operation of the substrate treatment system.

FIG. 8 is a schematic view for illustrating the operation of the substrate treatment system.

### DESCRIPTION OF EMBODIMENTS

Various embodiments will be illustrated hereinafter with reference to the accompanying drawings. The same reference numbers are applied to the same elements in figures, and detailed description will be omitted as appropriate.

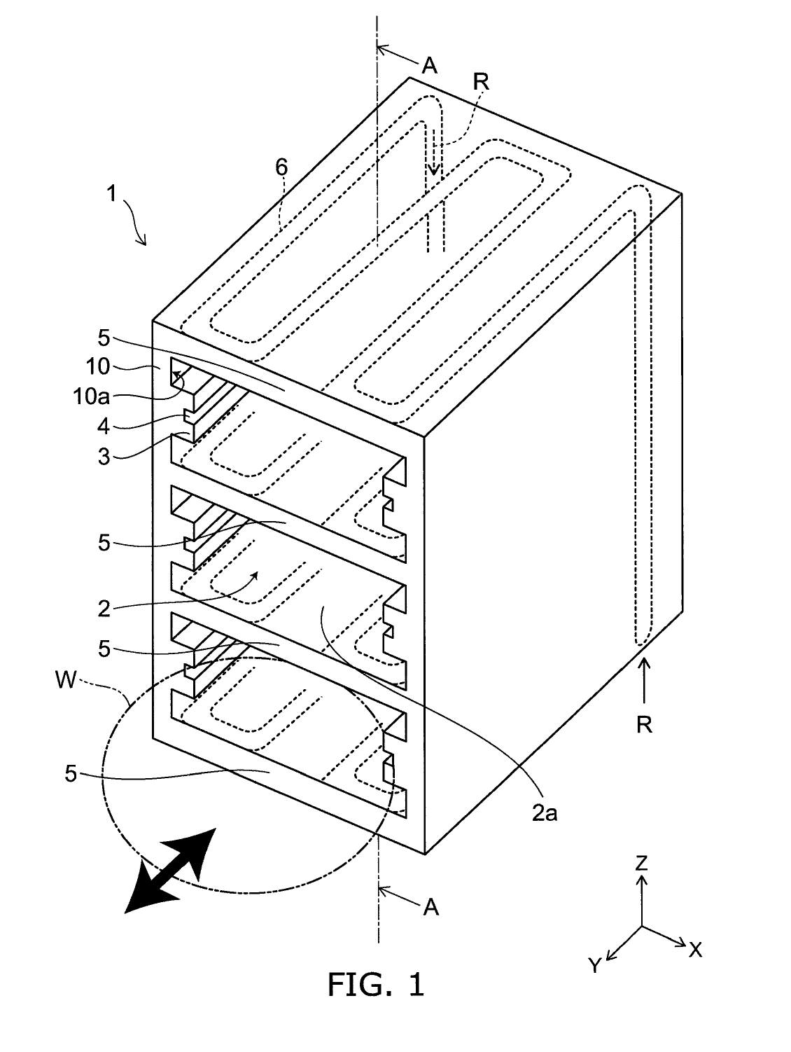

FIG. 1 is a schematic view for illustrating a substrate cooling device according to a first embodiment of the invention. Here, an arrow X, an arrow Y, an arrow Z in FIG. 1 represent three directions being orthogonal each other, the arrow X and the arrow Y represent a horizontal direction, and the arrow z represents a vertical direction.

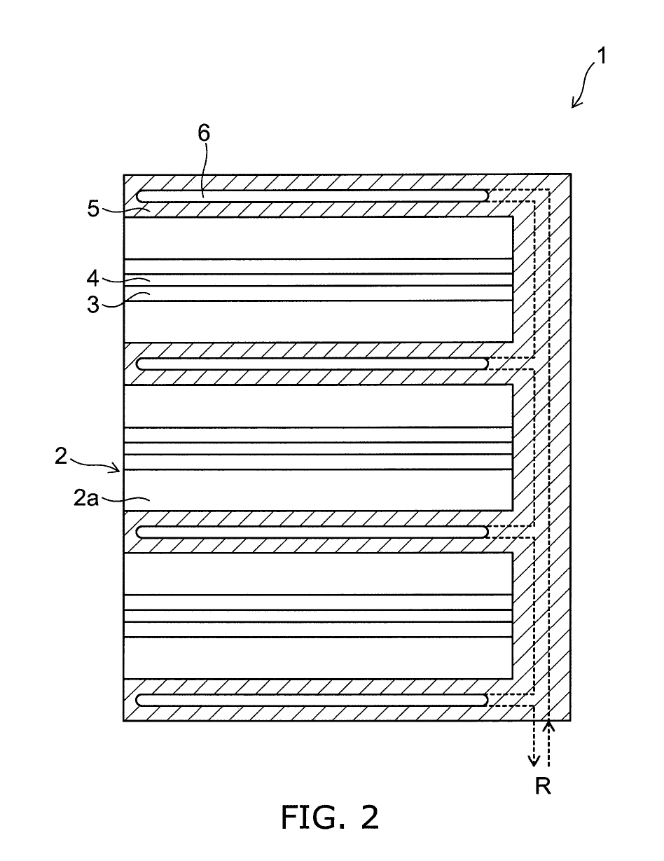

FIG. 2 is a sectional view as viewed along arrows A-A in FIG. 1. As shown in FIG. 1 and FIG. 2, one end side in the Y direction of a substrate cooling device 1 is opened for inserting a substrate W internally, and the substrate cooling device 1 includes a housing 10 having a space 2 housing the substrate W internally. A pair of holder sections 3 having groove sections 4 supporting an end neighborhood of the substrate W are provided on inner walls 10a of the housing 10 to face each other. The groove sections 4 are also provided on the holder sections 3 so that each pair of the grooves face each other.

A dimension in the X direction of the groove sections 4 (depth dimension of the groove section 4) is set to a dimension capable of supporting the substrate W stably. In this case, if the dimension in the X direction of the groove section 4 is too increased, scratches may be caused to occur and damage due to heat shock may be caused to occur. Therefore, the dimension in the X direction of the groove section 4 is preferably set to a minimum dimension required to support the substrate W stably.

A pair of holder sections 3 (groove sections 4) is provided in a plurality with a prescribed distance in the Z direction. The pair of holder sections 3 and a cooling section 5 are alternately provided in the Z direction. That is, the pair of holder sections 3 and the cooling section 5 are alternately provided in the direction (Z direction) crossing the direction (X direction) in which the holder sections 3 face each other. Therefore, end neighborhoods on mutually facing sides of the substrate W can be supported by the groove sections 4 and multiple substrates W can be configured to be supported with spacing in the space 2.

The cooling section 5 is provided so as to sandwich the pair of holder sections 3 (groove sections 4) in the Z direction. That is, the pair of cooling sections 5 are provided to include a cooling mechanism provided to sandwich the pair of holder sections 3 in the direction (Z direction) crossing the direction (X direction) in which the holder sections 3 face each other. Therefore, a space 2a is formed every pair of cooling sections 5, and thus the substrate W can be held every space 2a.

The cooling section 5 is provided with the cooling mechanism. The cooling mechanism can include, for example, one causing a cooling medium R to flow into a flow channel 6 provided inside the cooling section 5, as illustrated in FIG. 1 and FIG. 2. In the case like this, a supply mechanism (for example, pump or the like) not shown for causing the cooling medium R to flow into is connected to the flow channel 6. For example, it is configured that the cooling medium R can be circulated through the flow channel 6 formed in a loop shape. The flow channel can be configured freely to be spiral, lattice-shaped or the like other than illustrated. However, disposition and shape of the flow channel are preferable such that an in-plane temperature of the cooling section 5 is uniform as possible. A tank not shown storing the cooling medium 5 and a temperature control mechanism not shown performing temperature control of the cooling medium R or the like can be provided as appropriate.

The cooling medium R can include, for example, gaseous matter such as nitrogen and air, liquid matter such as water and fluorine-based liquid and gelled fluid matter or the like. However, the cooling medium R is not limited to illustrated one, but can be changed as appropriate.

The cooling mechanism is not limited to one causing the cooling medium R to flow into the flow channel 6, and a mechanism capable of cooling the cooling section 5 can be selected as appropriate. For example, it is configured that a Peltier element or the like can be provided as a cooling mechanism. In the case where other cooling mechanism such as a Peltier element is provided as well, disposition, shape and number are preferable such that the in-plane temperature of the cooling section 5 is uniform as possible.

Materials of the substrate cooling device 1 is not limited particularly, however, at least the cooling section 5 is preferable to be formed of materials having excellent thermal conductivity. Such materials, for example, can include metal materials such as aluminum alloy and stainless steel or the like. However, the materials are not limited to illustrated ones and can be selected as appropriate.

Next, the operation of the substrate cooling device 1 is illustrated.

The substrate W after the treatments of plasma treatment and thermal treatment is transferred by a transfer device not shown and the transferred substrate W is housed in the space 2a provided in the substrate cooling device 1. At this time, by inserting the substrate W into the groove section 4 provided on the holder section 3, the end neighborhood of the substrate W is supported, and the substrate W is held in the space 2a.

On the other hand, the cooling medium R is supplied into the flow channel 6 by the supply mechanism not shown, the flow channel being provided inside the cooling section 5. Circulation of the cooling medium R in the flow channel 6 cools the cooling section 5.

Here, because heat of the substrate W held in the space 2a is transferred to the cooling section 5 by radiation and convection in the space 2a, cooling of the substrate W is performed.

The substrate W after the cooling is taken out by the transfer device not shown to be housed in FOUP (Front Opening Unified Pod). The measurement of the substrate W temperature indicates whether the cooling of the substrate W is finished or not. The cooling time previously obtained by experiments or the like can also determine a finish time of the cooling.

According to the embodiment, because the temperature of the substrate W can be decreased before housing into the FOUP, the deformation and damage of the FOUP possibly caused by housing the substrate W with high temperature immediately after the treatment into the FOUP directly can be suppressed.

Here, if the substrate W with the high temperature immediately after the treatment is simply placed in air and cooled, a long time is required for the cooling, and thus production efficiency may be deteriorated.

According to the embodiment, the operation of the cooling section 5 can take heat actively from the substrate W. Moreover, because the cooling section 5 is provided so as to sandwich the pair of holder sections 3 (groove sections 4) in the Z direction, the heat can be taken from both major surfaces (front surface and back surface) of the substrate W. Therefore, the cooling time can be reduced. Consequently, the production efficiency can be improved.

The generally uniform cooling of the cooling section 5 can be performed by the operation of the cooling mechanism provided in the cooling section 5. For example, the flow channel 6 is provided in the cooling section 5 and the cooling medium R is configured to circulate in the flow channel 6. Alternatively, the cooling section 5 is provided with other cooling mechanism such as a Peltier element. Therefore, because a temperature gradient in the cooling section 5 can be decreased by the operation of the cooling mechanism, the generally uniform cooling of the cooling section 5 can be performed.

The generally uniform cooling of major surfaces on both sides of the substrate W can be performed by the cooling section 5 almost uniformly cooled. Therefore, the temperature difference between the major surfaces (front surface and back surface) on both sides of the substrate W and the distribution of the in-plane temperature of the substrate W can be reduced. Consequently, occurrence of the warpage and strain of the substrate W can be suppressed.

Particularly, in the case where the disposition, the shape and the number or the like of the cooling mechanism are configured so that the in-plane temperature of the cooling section 5 is uniform as possible, the temperature gradient of the cooling section 5 can be more reduced. Therefore, because the cooling section 5 can be cooled further uniformly, the major surfaces on both sides of the substrate W can be cooled further uniformly. Consequently, because the temperature difference between the major surfaces (front surface and back surface) on both sides of the substrate W and the distribution of the in-plane temperature of the substrate W can be further reduced, the occurrence of the warpage and the strain of the substrate W can be further suppressed.

In the case where the multiple substrates W are only housed in order to improve the production efficiency, thermal interference between the substrates may elongate the cooling time or produce a temperature variation. Particularly, because the heat of the substrate W housed down below is transferred to the substrate W housed above by the convection, the cooling time of the substrate W housed above may elongate.

In the embodiment, because the cooling section 5 is provided so that the inside of the space 2a extends in the XY direction, the thermal interference between the substrates housed in the Z direction can be suppressed. That is, because the substrate W is held inside the space 2a of which both ends in the Z direction are partitioned by the cooling sections 5, the heat transfer from the substrate W housed downward to the substrate W housed upward can be suppressed. Therefore, homogenization and reduction of the cooling time is possible and the occurrence of the temperature difference depending on the housing position (housing position in Z direction) can be suppressed as well.

FIG. 1 and FIG. 2 illustrate the cases where one substrate W is housed in every space 2a, however the multiple substrates W can be housed in every space 2a as well. That is, a pair of holder sections 3 can be provided in a plurality between a pair of cooling sections 5. However, from the viewpoint of reduction of the cooling time and uniformity of the temperature of the substrate W, it is preferable that the number of the substrates W housed in every space 2a is reduced.

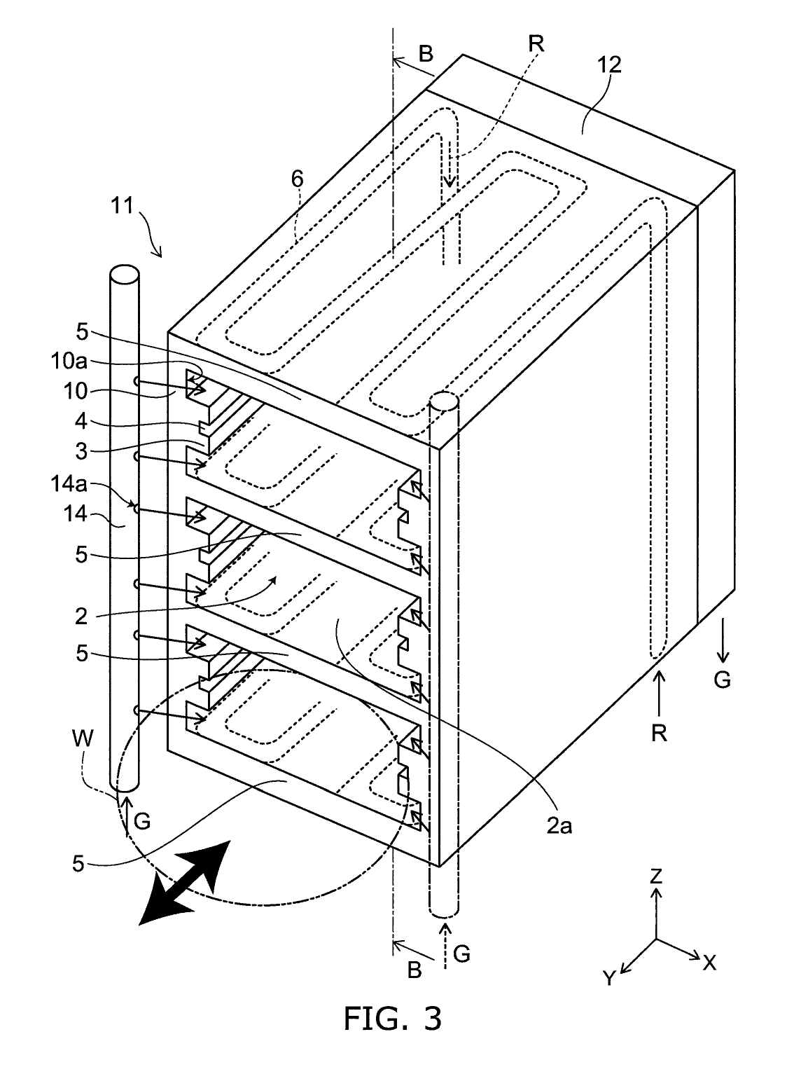

FIG. 3 is a schematic view for illustrating a substrate cooling device according to a second embodiment of the invention. Here, an arrow X, an arrow Y, an arrow Z in FIG. 3 represent three directions being orthogonal each other, the arrow X and the arrow Y represent a horizontal direction, and the arrow z represents a vertical direction.

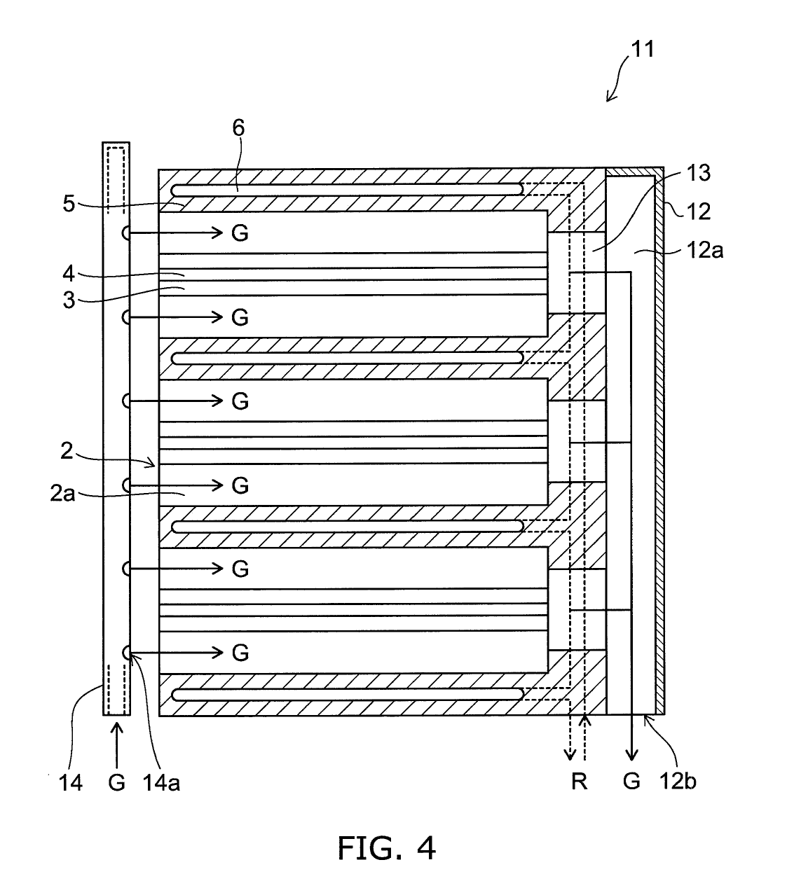

FIG. 4 is a sectional view as viewed along arrows B-B in FIG. 3. As shown in FIG. 3 and FIG. 4, a substrate cooling device 11 includes the housing 10 having the space 2 housing the substrate W internally similar to the foregoing substrate cooling device 1. A pair of holder sections 3 having groove sections 4 supporting an end neighborhood of the substrate W are provided on inner walls 10a of the housing 10. The cooling section 5 is provided so as to sandwich the pair of holder sections 3 (groove sections 4) in the Z direction. That is, the pair of cooling section 5 having the cooling mechanism sandwiching the pair of holder sections 3 in the direction (Z direction) crossing the direction (X direction) in which the holder sections 3 face each other. The cooling mechanism can be similar to that of the foregoing substrate cooling device 1.

One end side in the Y direction of the substrate cooling device 11 (housing 10) is opened for inserting the substrate W internally. A gas introduction mechanism 14 for introducing a gas G toward the space 2 is provided on the opened end side. That is, the gas introduction mechanism 14 is provided for introducing the gas from the one end side of the housing 10 into the space 2a formed between the pair of cooling sections 5. The gas introduction mechanism 14 can be provided at a position where installation (insertion) and taking out of the substrate W is not disturbed, however, for example, can be evacuated when installation (insertion) and taking out by providing a transportation mechanism not shown as well. A gas exhaust mechanism 12 for exhausting the gas introduced toward the space 2a is provided on a side facing a side provided with the gas introduction mechanism 14. That is, the gas exhaust mechanism 12 for exhausting the introduced gas is provided on the end surface of the side facing the end surface side provided with the gas introduction mechanism 14.

The gas introduction mechanism 14 can be, for example, a nozzle including an ejection hole 14a as shown in FIG. 3, FIG. 4. The gas introduction mechanism 14 is tubular and its one end is stopped. A gas supply mechanism not shown is connected to the other end. The gas supply mechanism not shown includes, for example, a high-pressure gas bomb and a gas supply machine or the like provided in a factory. A control mechanism not shown for controlling a flow rate and a pressure of the gas G supplied to the gas introduction mechanism 14 can be provided as appropriate.

The multiple ejection hole 14a provided in the gas introduction mechanism 14 are provided on a portion facing every space 2a so that the gas G can be introduced into every space 2a. The ejection hole 14a is provided on a position where the gas G can be introduced into a space formed between one of major surfaces on both sides of the substrate W (front surface or back surface of the substrate W) held on the holder section 3 (groove section 4) and the cooling section 5. That is, the gas introduction mechanism 14 introduces the gas G into the space 2a formed between the pair of cooling sections 5 along a major surface of the cooling section 5. The gas introduction mechanism 14 introduces the gas G into the space 2a formed between the pair of cooling sections 5 along the major surfaces of the substrate W.

As shown in FIG. 4, a gas exhaust 13 is provided on an end on a side facing a side on which the gas introduction mechanism 14 is provided. The gas exhaust 13 of every space 2a is provided.

The gas exhaust mechanism 12 is provided so as to cover the gas exhaust 13 and a space 12a formed inside is communicated to the space 2a through the gas exhaust 13. An exhaust port 12b for connecting to an exhaust device not shown is provided on one end of the gas exhaust mechanism 12 in the Z direction. The exhaust device not shown can include an exhaust machine or the like provided in a factory. The exhaust device not shown is not always necessary, however providing the exhaust device not shown allows the flow of the gas G in the space 2a to be smooth.

The gas G introduced by the gas introduction mechanism 14 is not limited particularly, however is preferred to be one uneasy to chemically react with the substrate W at a high temperature. Such a gas can include, for example, an inactive gas such as nitrogen.

Next, the operation of the substrate cooling device 11 is illustrated.

The substrate W after the treatments of plasma treatment and thermal treatment is transferred by a transfer device not shown and the transferred substrate W is housed in the space 2a provided in the substrate cooling device 1. At this time, by inserting the substrate W into the groove section 4 provided on the holder section 3, the end neighborhood of the substrate W is supported, and the substrate W is held in the space 2a.

On the other hand, the cooling medium R is supplied into the flow channel 6 by the supply mechanism not shown, the flow channel being provided inside the cooling section 5. Circulation of the cooling medium R in the flow channel 6 cools the cooling section 5.

The gas G is introduced from the gas introduction mechanism 14 into every space 2a. The introduced gas G flows through the space formed between one of major surfaces on both sides of the substrate W (front surface or back surface of the substrate W) and the cooling section 5 along the major surfaces of the substrate W and the cooling section 5 and is exhausted to the space 12a formed inside the gas exhaust mechanism 12 through the gas exhaust 13. The gas G exhausted to the space 12a is exhausted toward the exhaust device not shown through the exhaust port 12b.

The substrate W after the cooling is taken out by the transfer device not shown to be housed in FOUP (Front Opening Unified Pod). The measurement of the substrate W temperature indicates whether the cooling of the substrate W is finished or not. The cooling time previously obtained by experiments or the like can also determine a finish time of the cooling.

According to the embodiment, because the temperature of the substrate W can be decreased before housing into the FOUP, the deformation and damage of the FOUP possibly caused by housing the substrate W with high temperature immediately after the treatment into the FOUP directly can be suppressed.

A part of the heat of the substrate W held in the space 2a is transferred to the cooling section 5 by radiation, however main part is transferred to the gas G. Because the heat of the substrate W is transferred, the gas G with elevated temperature is exhausted to the gas exhaust mechanism 12 through the gas exhaust 13. Therefore, temperature increase of the gas G in the space 2a is suppressed, and thus heat transfer to the gas G can be improved. Because the gas G with the elevated temperature is cooled with the cooling section 5, the heat transfer to the gas G can be further improved. Consequently, the cooling time can be further reduced. Production coefficiency can be further improved as well.

Because the gas G is cooled with the cooling section 5, temperature gradient of the gas G flowing in the space 2a can be decreased. That is, the temperature difference between a neighborhood of a portion to which the gas G is introduced and a neighborhood of the gas exhaust 13 to which the gas G is exhausted can be reduced. Therefore, the substrate W temperature can be uniformed and occurrence of the warpage and the strain can be suppressed.

Similar to the foregoing substrate cooling device 1, because the substrate W is held inside the space 2a of which both ends in the Z direction are partitioned by the cooling sections 5, the heat transfer from the substrate W housed downward to the substrate W housed upward can be suppressed. Therefore, homogenization and reduction of the cooling time is possible and the occurrence of the temperature difference depending on the housing position can be suppressed as well.

FIG. 3 and FIG. 4 illustrate the cases where one substrate W is housed in every space 2a, however the multiple substrates W can be housed in every space 2a as well. That is, a pair of holder sections 3 can be provided in a plurality between a pair of cooling sections 5. Also in this case, introduction of the gas G into the space formed between the substrates W allows rapid cooling and temperature uniformity of the substrate W. Housing multiple substrates W in every space 2a can improve the production efficiency and space efficiency.

However, from the viewpoint of reduction of the cooling time and the temperature uniformity of the substrate W, it is preferable that the number of the substrates W housed in every space 2a is reduced.

Next, a substrate treatment system 100 according to the embodiment is illustrated.

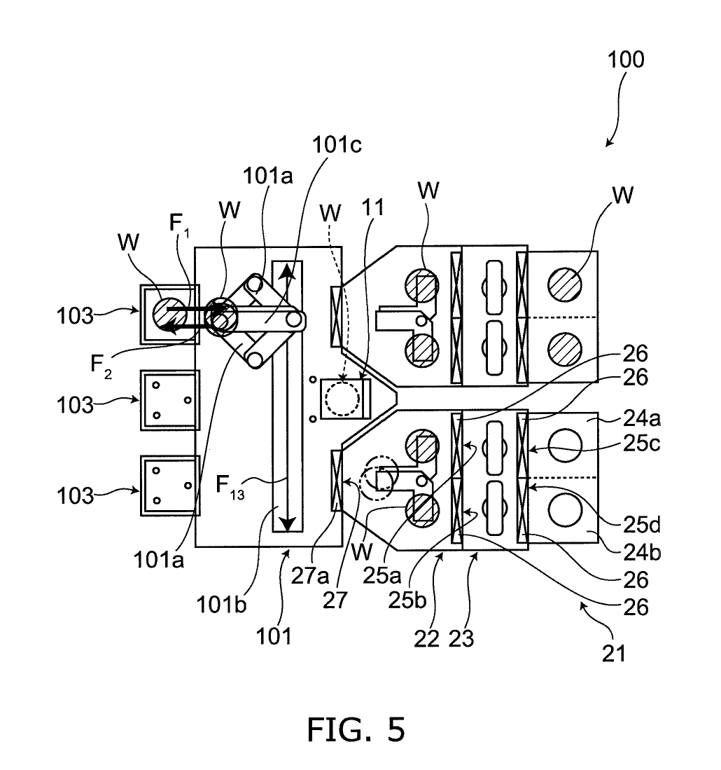

FIG. 5 is a schematic view for illustrating a substrate treatment system according to a third embodiment of the invention.

As shown in FIG. 5, the substrate treatment system 100 includes a treatment device 21 configured to treat the substrate W, a housing device 103 configured to house the substrate W, and the substrate cooling device 11. A transfer device 101 configured to transfer the substrate W among the treatment device 21, the housing device 103 and the substrate cooling device 11 is provided. In the case shown in FIG. 5, the substrate cooling device 11 is provided, however the substrate cooling device 1 may be provided.

The treatment device 21 is, for example, illustrated as the plasma treatment and the heat treatment of the substrate W. The configuration of the treatment device 21 can be modified as appropriate depending on the substrate W and the treatment. The plasma treatment of the substrate W can be illustrated as an ashing, an etching and a film forming or the like for a wafer of a semiconductor device and an etching and a film forming or the like for a wafer of a liquid crystal display device.

Here, one example of the treatment device 21 is described as a device for the plasma treatment of the wafer. The treatment device 21 is a so-called mufti-chamber style treatment device including multiple treatment chambers.

The treatment device 21 includes a load-lock chamber 22 capable of decreasing inner pressure, a transfer chamber 23, and treatment chambers 24a, 24b. Multiple transfer ports 25a, 25b are formed in parallel on a wall surface between the load-lock chamber 22 and the transfer chamber 23 and multiple transfer ports 25c, 25d are formed in parallel on a wall surface between the transfer chamber 23 and the treatment chambers 24a, 24b. The load-lock chamber 22 and the transfer chamber 23 the transfer chamber 23 and treatment chambers 24a, 24b are connected to have an inner space communicated via the transfer ports 25a, 25b. The transfer chamber 23 and the treatment chambers 24a, 24b are connected to have an inner space communicated via the transfer ports 25c, 25d.

Gate valves 26 are provided so as to be capable of projecting downward, and the gate valves 26 allow the transfer ports 25a to 25d to be closed air-tightly.

A transfer port 27 is provided also on one other sidewall of the load-lock chamber 22 (sidewall on a side facing the transfer chamber 23 side), and a vacuum valve 27a allows the transfer port 27 to be closed air-tightly.

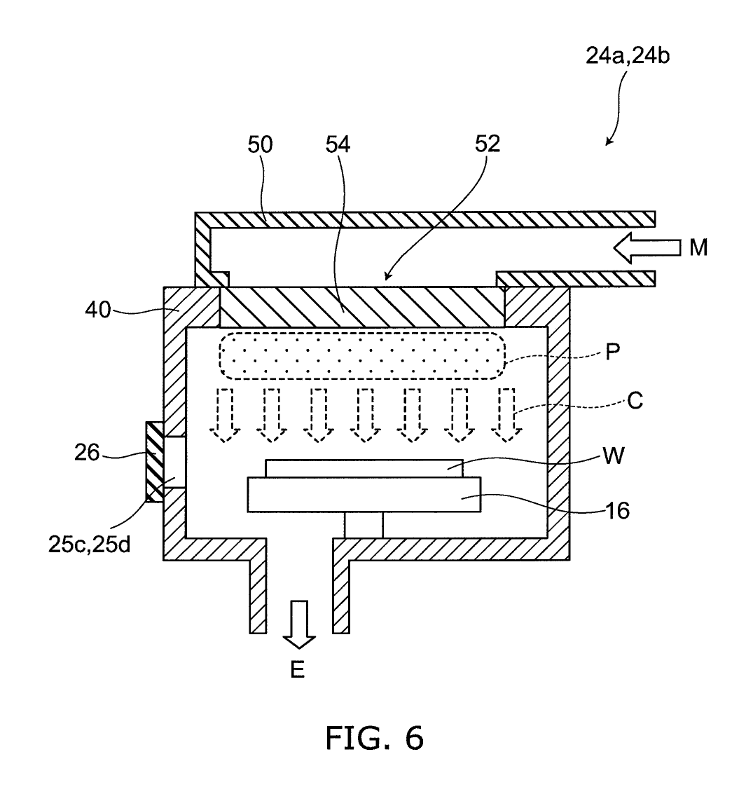

FIG. 6 is a schematic sectional view for illustrating the configuration of the treatment chambers 24a, 24b.

The treatment chambers 24a, 24b are provided with a treatment vessel 40, a wave guide body (transmission window) 54 made of plane-shaped dielectric plate provided on an upper surface of the treatment chamber 40, and an introduction wave guide tube 50 provided outside the wave guide body 54. A portion of the wave guide tube 50 in abutment with the wave guide body 54 is provided with a slot antenna 52 for introducing microwave M into the wave guide body 54. A stage 16 is provided inside the treatment vessel 40 for placing and holding the substrate W such as a wafer.

The treatment vessel 40 is capable of maintaining a reduced pressure formed by a reduced pressure evacuation system E, and provided with a gas introduction tube (not shown) for introducing a treatment gas into the space where the plasma P is generated as appropriate.

The transfer ports 25c, 25d are provided on one sidewall of the treatment vessel 40 as described previously, and the gate valves 26 allow the transfer ports 25c, 25d to be closed air-tightly.

The transfer device 101 is provided with an arm 101a having a joint. The arms 101a are provided separately one above the other. A hold mechanism capable of placing and holding the substrate is provided on a tip of the arm 101a. The hold mechanism is not shown. An arm base 101c provided with the arm 101a is connected to a transport mechanism 101b and the arm base 101c is capable of traveling in a direction of an arrow F₁₃. Therefore, the arm 101a is expanded and contracted by inflection, and is capable of moving in the direction of the arrow F₁₃ while placing and holding the two substrates W on the tip of the arm 101a. A mechanism adjusting a rotation direction of the substrate W and a position in a vertical direction not shown and a mechanism for changing the direction of the arm 101a by rotating the base of the arm 101a are provided.

The housing device 103 is a device for housing the substrate W after a plasma pre-treatment and the plasma treatment, and for example, can be illustrated as a wafer carrier capable of housing the substrates W in a stacked manner (multistage manner). Specifically, FOUP can be included, which is a front opening style carrier for transfer and storage of the substrate W used in a mini environment style semiconductor factory. An opening and closing device for a front door of the carrier or the like can be provided as appropriate.

The substrate cooling device 11 is a device for cooling the substrate W after the plasma treatment. The plasma treatment increases the temperature of the substrate W as an object to be processed. Therefore, when housing it in a carrier or the like made of a resin, the temperature is required to be cooled. As described previously, in the substrate cooling device 11 according to the embodiment, the cooling time can be reduced, and thus the production efficiency can be improved. The occurrence of the warpage and the strain of the substrate W can be suppressed.

Next, the operation of the substrate treatment system 100 is illustrated with reference to FIG. 5 to FIG. 8.

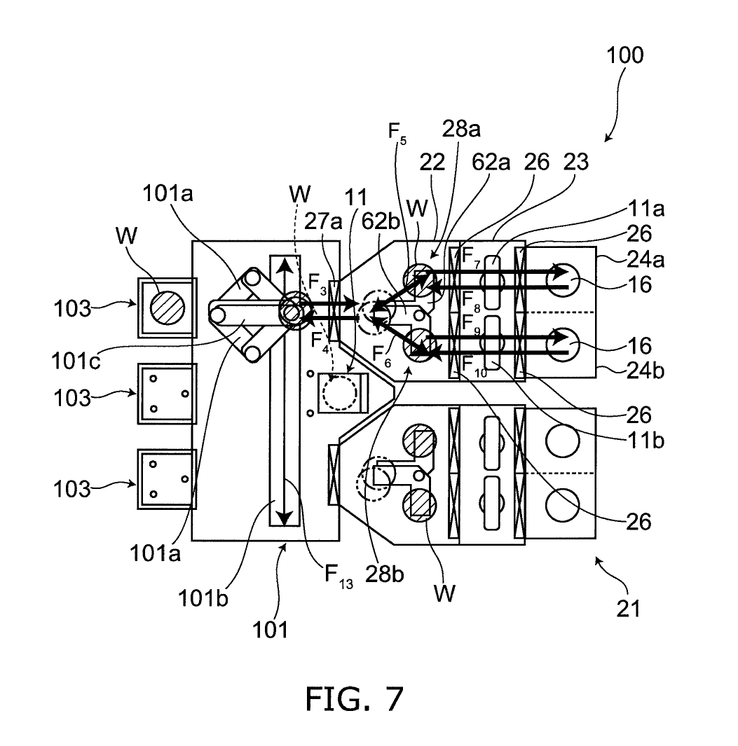

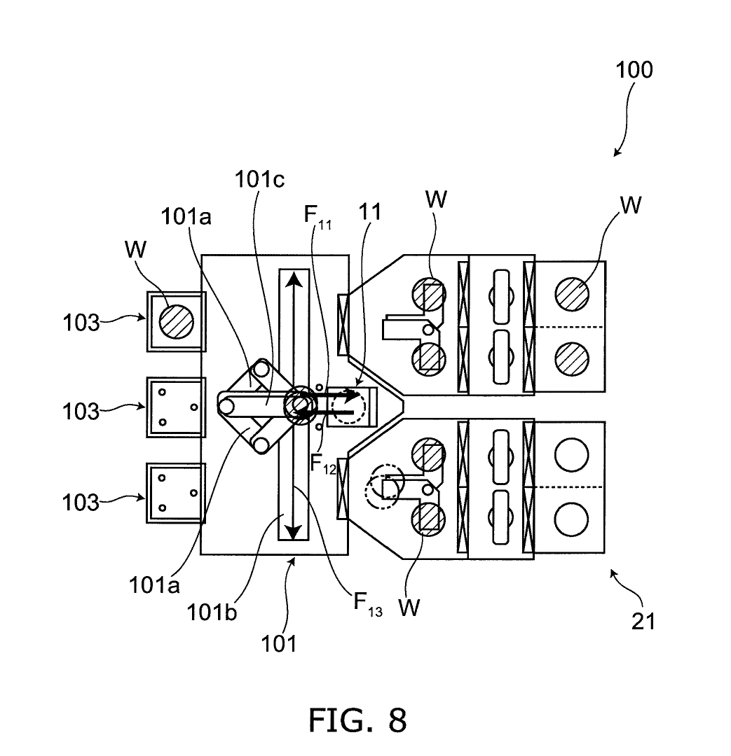

FIGS. 7 and 8 are schematic views for illustrating the operation of the substrate treatment system.

First, as shown in FIG. 5, the arm base 101c of the transfer device 101 is moved to a prescribed front face of the housing device 103. The opening and closing device not shown opens the door of the housing device 103. Next, the arm 101a is extended in a direction of an arrow F₂ by inflecting the arm 101a, and two substrates W are received in a state with a vertical prescribed space. The arm 101a is contracted in a direction of an arrow F₁ by inflecting. The substrates W are taken out from the housing device 103.

Next, as shown in FIG. 7, the arm 101a is rotated by 180°, and is caused to face the treatment device 21. At that time, the position of the arm base 101c is adjusted as appropriate so that the arm 101a comes at the front of the treatment device 21.

Next, the arm 101a is extended in a direction of an arrow F₃ by inflection, and two substrates W are transferred to fingers 62a, 62b of a robot device in a state with a vertical prescribed space. Thereafter, the arm 101a is contracted in a direction of an arrow F₄ by inflection and evacuated from the load-lock chamber 22. The load-lock chamber 22 is closed with the vacuum valve 27a air-tightly and the inside pressure is reduced to a prescribed value.

Next, the finger 62a is rotated by 90° in a direction of an arrow F₅ and the finger 62b is rotated by 90° in a direction of an arrow F₆. The two substrates W are sorted to a first transfer position 28a and a second transfer position 28b. The substrates W are pushed up to a prescribed height by push-up pins not shown at the first transfer position 28a and the second transfer position 28b.

Fingers not shown of a robot devices 11a, 11b provided in the transfer chamber 23 are inserted down below the pushed up substrates W. After that, the push up pins are moved down and the substrates W are transferred onto the fingers not shown of the robot devices 11a, 11b.

Next, the robot devices 11a, 11b are rotated and the substrates W are transferred in directions of arrows F₇, F₉ (directions of the treatment chambers 24a, 24b) in the transfer chamber 23. The substrates W are installed into the treatment chambers 24a, 24b. The transfer chamber 23 is also closed with the gate valves 26 air-tightly and the inside pressure is reduced to a prescribed value.

Next, the substrates W are transferred to the stages 16 in the treatment chambers 24a, 24b by the push up pins not shown or the like. After evacuation of the robot devices 11a, 11b, the treatment chambers 24a, 24b are closed with the gate valves 26 and the plasma treatment is performed.

As shown in FIG. 6, in the plasma treatment, first, the pressure in the treatment vessel 40 is reduced to a prescribed value through the reduced pressure evacuation system E, and the prescribed treatment gas is introduced toward the space of plasma P generation in the treatment vessel 40.

On the other hand, for example, the microwave M of 2.45 GHz is introduced into the wave guide tube 50 from a microwave power supply not shown. The microwave M transmitted through the wave guide tube 50 is introduced into the wave guide body 54 via the slot antenna 52. The wave guide body 54 is made of a dielectric body such as quartz and alumina, and the microwave M transmits along a surface of the wave guide body 54 as a surface wave to be radiated toward the space of the plasma P generation in the treatment vessel 40.

Energy of the microwave M radiated toward the space of the plasma P generation in that manner forms the plasma P of the treatment gas. When an electron density in the plasma P generated in this manner becomes greater than a density (cut off density) capable of screening the microwave M introduced through the wave guide body 54, the microwave M is reflected within a certain distance (skin depth) penetrating from a lower surface of the wave guide body 54 toward the space of the plasma P generation in the chamber, and a standing wave of the microwave M is formed.

Then, a reflection face of the microwave M serves as a plasma excitation face and the plasma P results in being excited stably on the plasma excitation face. In the plasma P excited on the plasma excitation face, collisions of an ion and electron with a molecule of the treatment gas generate excited active species (plasma products) such as excited molecules and atoms, free atoms (radical). Those plasma products diffuse in the treatment vessel 40 as shown by arrows C and arrive at the surface of the substrate W, and then the plasma treatment is performed.

Here, because a plasma treatment condition or the like is obtained from known techniques, its detailed description is omitted.

The substrates W after the plasma treatment are transferred to the arm 101a of the transfer device 101 in a sequence reverse to the foregoing case. That is, the substrates W are transferred in directions of arrows F₈·F₁₀, F₅·F₆, F₄ in FIG. 7 and transferred to the arm 101a of the transfer device 101.

Next, as shown in FIG. 8, the arm base 101c is moved to the front of the substrate cooling device 11. The arm 101a is extended in a direction of an arrow F₁₁ by inflection and the substrate W is transferred to the substrate cooling device 11. If the substrate cooling device 11 is able to house the multiple substrates W in the space 2a, two substrates W can be transferred to the substrate cooling device 11 in a state with a prescribed vertical spacing.

The substrate W after the cooling is received and evacuated from the substrate cooling device 11 by inflecting and contracting the arm 101a in a direction of an arrow F₁₂.

The cooling of the substrate W is similar to that illustrated in the operation of the substrate cooling device 11, and thus the description is omitted.

Next, the arm base 101c is moved to the front of the housing device 103. The arm 101a is rotated by 180° and extended in the direction of the arrow F₂, and the substrate W is transferred to the housing device 103. If the substrate cooling device 11 is able to house the multiple substrates W in the space 2a, two substrates W are received from the substrate cooling device 11 in a state with a prescribed vertical spacing and can be transferred to the housing device 103.

The substrate W taken out from the housing device 103 is controlled to be housed into the same position of the same housing device 103. After that, if necessary, the foregoing sequence is repeated and the treatment for the substrate W is performed sequentially.

The embodiment of the invention has been described. However, the invention is not limited to these descriptions.

Design modifications appropriately made by one skilled in the art in regard to the embodiments described above are within the scope of the invention to the extent that the purport of the invention is included.

For example, shape, dimension, material and disposition or the like of components included in the substrate cooling device 1, the substrate cooling device 11 and the substrate treatment system 100 are not limited to the illustrated examples, but can be modified appropriately.

The components included in the embodiments described above can be combined to the extent possible, and these combinations are also encompassed within the scope of the invention as long as they include the features of the invention.

### INDUSTRIAL APPLICABILITY

As described in detail, according to the invention, a substrate cooling device and a substrate treatment system capable of reducing a time required for cooling a substrate after treatment can be provided and industrial merits are great.

### EXPLANATION OF REFERENCE

1 substrate cooling device

2 space

2a space

3 holder section

4 groove section

5 cooling section

6 flow channel

10 housing

10a inner wall

11 substrate cooling device

12 gas exhaust mechanism

12a space

12b exhaust port

13 gas exhaust

14 gas introduction mechanism

14a ejection hole

21 treatment device

100 substrate treatment system

101 substrate transfer device

103 housing device

G gas

R cooling medium

W substrate

What is claimed is:

1. A substrate cooling device configured to cool a substrate after a treatment, the device comprising:
a housing having a space configured to house a substrate internally;
a pair of holder sections provided so as to face an inner wall of the housing, and including a groove section supporting an end neighborhood of the substrate;
a pair of cooling sections including a cooling mechanism provided to sandwich the pair of holder sections in a direction crossing a direction in which the holder sections face each other;
a gas introduction mechanism configured to introduce a gas from one end face side of the housing into the space partitioned by the pair of cooling sections; and
a gas introduction mechanism introduces the gas into the space partitioned by the air of coolin sections alon a ma or surface of the housed substrate.

2. The device according to claim 1, wherein the substrate is held inside the space partitioned by the pair of cooling sections.

3. The device according to claim 1, further comprising:
a gas exhaust mechanism provided on an end face of a side facing the end face side on which the gas introduction mechanism is provided, and configured to exhaust the introduced gas.

4. The device according to claim 1, wherein the gas introduction mechanism introduces the gas into the space partitioned by the pair of cooling sections along a major surface of the cooling sections.

5. (canceled)

6. The device according to claim 1, wherein the pair of holder sections and one of the cooling sections are alternately provided in the direction crossing the direction in which the holder sections face each other.

7. The device according to claim 1, wherein the pair of holder sections are provided in a plurality inside the space partitioned by the pair of cooling sections.

8. A substrate treatment system comprising:
a treatment device configured to perform a treatment of a substrate;
a housing device configured to house the substrate;
a substrate cooling device; and
a transfer device configured to transfer the substrate between the treatment device and the substrate cooling device and between the substrate cooling device and the housing device,
the substrate cooling device configured to cool the substrate after the treatment, the device including:
a housing having a space configured to house the substrate internally;
a pair of holder sections provided so as to face an inner wall of the housing, and including a groove section supporting an end neighborhood of the substrate;
a pair of cooling sections including a cooling mechanism provided to sandwich the pair of holder sections in a direction crossing a direction in which the holder sections face each other;
a gas introduction mechanism configured to introduce a gas from one end face side of the housing into the space partitioned by the pair of cooling sections; and
the gas introduction mechanism introduces the gas into the space partitioned by the pair of cooling sections along a major surface of the housed substrate.
